(19) United States
(12) Patent Application Publication
(10) Pub. No.: US 2006/0028792 A1
(43) Pub. Date: Feb. 9, 2006

(54) Portable electronic device with illumination indication for input

(75) Inventor: Chien-Li Wu, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/025,707

(22) Filed: Dec. 28, 2004

(30) Foreign Application Priority Data
Aug. 3, 2004 (TW) 093212281

(51) Int. Cl. G02F 1/1333; H05K 5/00

(52) U.S. Cl. 361/683

(57) ABSTRACT

A portable electronic device with illumination indication for input is provided, which includes a main body having an input unit, a display unit pivotally connected to the main body, and illumination units provided on two sides of the input unit. Each of the illumination units includes a liftable light shield pivotally connected to the input unit and a plurality of illuminators provided in the liftable light shield, such that the illumination units illuminate the input unit to facilitate a user to operate the main body under a dark or light insufficient environment.

### FIELD OF THE INVENTION

The present invention relates to portable electronic devices with illumination indication for input, and more particularly, to a portable electronic device having an illumination unit for providing illumination on an input unit thereof.

### BACKGROUND OF THE INVENTION

Due to fast development of the computer industry, computer users are increasingly seeking convenience in operation of computers, and accordingly the computers have been evolved from desktop computers to portable notebooks. The notebook computer is characterized in having a foldable structure that allows its LCD (liquid crystal display) monitor to act as a lid and be closed when carrying the computer, thus reducing the occupied space of the notebook computer and making the notebook computer portable and easily carried. Therefore, the notebook computers gradually become popular besides the desktop computers.

The notebook computers provide considerable convenience in use but are not perfect enough, and there still exits certain inconvenience when operating the notebook computers. For example, in an environment without sufficient light or with completely no light, such as a cafe, outdoor square, car, or even countryside, a user may not be very familiar with key positions of a keyboard of the notebook computer and thus not able to smoothly operate the keyboard and the notebook computer under such condition with insufficient illumination. This thereby causes troubles using the notebook computers.

Moreover, the wide application of a wireless network is considered as a trend in the near future to allow the users of the notebook computers to access a broadband network anytime and anywhere. There are more and more system providers to provide the wireless network service on the market. Some of the high-end notebook computers have been internally built with a wireless network module as standard equipment, and the notebook computers without the built-in wireless network module can adopt a wireless network card designed with PCMCIA (Personal Computer Memory Card International Association) interface to access the network wirelessly. The new generation of wireless notebook computers has become mainstream products on the market, which can be used for long hours and remain standby for a whole day. However, operation of the notebook computers would still be limited in suburban areas at night under a condition without sufficient light. Although weak illumination may be provided by the liquid crystal displays of the notebook computers, it is too dim to operate the keyboards of the computers.

In order to solve the problem of failure to use the keyboard of the notebook computer in a light insufficient environment, there has been proposed to mount an illuminating device under the keys of the keyboard such that the illuminating device illuminates the keyboard in the dark for the user to operate the keys, as disclosed in for example, U.S. Pat. Nos. 6,057,517, 6,648,530, 6,322,229, 6,561,668, and 6,467,924, etc.

The above keyboard with the illumination effect as disclosed in U.S. Pat. No. 6,467,964 is shown in FIG. 4. Referring to FIG. 4, an elastic press-cap 42 is provided above a key-disposed position 411 on a printed circuit board 41. A light-conducting layer 43 is formed on the elastic press-cap 42, and a hollow tube 431 is provided on the light-conducting layer 43 at a position corresponding to the elastic press-cap 42, wherein an opaque plated film 432 is applied on a surface of the light-conducting layer 43. A key 44 with a key axis 441 is inserted into the hollow tube 431. A transparent symbol surface 443 is formed on a top surface of a key cap 442 of the key 44, and the transparent symbol surface 443 is disposed at a top end of the key axis 441. This allows light to be introduced via the light-conducting layer 43 into the key 44 and then guided to the top surface of the key 44 via the key axis 441 so as to radiate light from the symbol surface 443 on the top surface of the key 44, such that the key position can be clearly indicated in the dark or under a condition without sufficient light for the user to operate of the keyboard.

However, the structure for introducing light to the key 44 via the light-conducting layer 43 is rather complicated, thus making the fabrication cost increased. Further, the provision of light-conducting layer 43 above the printed circuit board 41 increases the thickness of the keyboard, which does not help reduce the size of the notebook computer.

Referring to FIG. 5 showing a conventional structure disclosed in U.S. Pat. No. 6,561,668, a light source 523 is provided in front of a keyboard 522 of a notebook computer 521, and a light shield 524 is mounted above the light source 523. This allows light irradiated from the light source 523 to be projected at the keyboard 522 and thus provides illumination for the keyboard 522 at night or under a condition without sufficient light.

However, the light source 523 is disposed between the keyboard 522 and a liquid crystal display 525. In such case, keys of the keyboard 522 that are located most closely to the user are most distant from the light source 523 and receive the weakest illumination not able to allow the user to recognize the symbols on the keys. Thus, the light intensity of the light source 523 needs to be increased to provide enough illumination for those keys located distantly. This however would increase the consumption of electrical power and shorten the operation time of the notebook computer 521. Further since the light source 523 is disposed between the keyboard 522 and the liquid crystal display 525, and the liquid crystal display 523 and the light source 523 differ in light intensity thereof and are located in different upper and lower areas respectively, it would cause visual confusion for the user and inconvenience in use.

Accordingly, U.S. Pat. No. 6,561,668 also discloses a top illumination structure. Referring to FIGS. 6A and 6B, this structure comprises an illuminator 63 provided on a top edge of the liquid crystal display 525 of the notebook computer 521. The illuminator 63 includes an LED (light emitting diode) 632 mounted inside a casing 631. When the notebook computer 521 is to be used in the dark or under the condition without sufficient light, the user may open the liquid crystal display 525 and switch on the illuminator 63 to illuminate the keyboard 522. This can reduce a difference in light intensity between the irradiated keyboard 522 and the liquid crystal display 525 and avoid the visual interference or confusion for the user.

However, since the illuminator 63 is mounted to the top edge of the liquid crystal display 525 by a fixed angle, after the user opens the liquid crystal display 525, only a certain area on the keyboard 522 is capable of being effectively illuminated by the illuminator 63. The user may open the liquid crystal display 525 by an angle relative to the keyboard 522 according to personal habit. Particularly, the greater the angle of the liquid crystal display 525 being opened relative to the keyboard 522, the closer the illuminated area to the user is. In such case, keys of the keyboard 522 that are close to the liquid crystal display 525 would receive weak illumination. This makes the light intensity varied in different regions of the irradiated keyboard 522, such that the user needs to adjust the opening angle of the liquid crystal display 525 according to the irradiating angle of the illuminator 63.

Moreover, as the illuminator 63 is located on the top edge of the liquid crystal display 525, light is irradiated downwardly from the illuminator 63. When the user reaches his fingers to the keyboard 522, the fingers may block the light and cause shadows on the keyboard 522 such that symbols on the keys blocked by the shadows become difficult to recognize, thereby influencing the user's operation of the keyboard 522.

### SUMMARY OF THE INVENTION

In light of the above prior-art drawbacks, an objective of the present invention is to provide a portable electronic device with an input unit having an illumination unit so as to allow operation of the electronic device in an environment without sufficient light.

Another objective of the present invention is to provide a portable electronic device, having an illumination unit disposed on two sides of an input unit respectively so as to prevent light from being blocked by fingers of a user to influence operation.

Still another objective of the present invention is to provide a portable electronic device with an illumination unit that can reduce a difference in light intensity between an irradiated input unit and a display unit, so as to avoid visual discomfort to affect operation for a user.

A further objective of the present invention is to provide a portable electronic device with an illumination unit that can be stored or received inside an input unit and thus would not affect the appearance when not being used.

In order to achieve the above and other objectives, a portable electronic device is proposed according to a preferred embodiment of the present invention, including a main body having an input unit, a display unit pivotally connected to the main body, and at least one illumination unit mounted on two sides of the input unit respectively and for illuminating the input unit. The illumination unit includes a liftable light shield pivotally connected to the input unit, and a plurality of illuminators provided in the light shield. The illuminators can irradiate light onto the input unit when the liftable light shield is lifted, such that the input unit can be illuminated under a condition without sufficient light or in the dark for a user to operate the input unit.

Since the illumination units are mounted on two sides of the input unit to irradiate light from the two sides to the input unit, a great difference in light intensity between the irradiated input unit and the display unit can be avoided thereby not causing visual discomfort for the user to influence the user's operation of the portable electronic device under the condition without sufficient light or in the dark. Further since the illumination units irradiate the light from the sides of the input unit, this prevents the light from being blocked by fingers of the user to cause shadows on the input unit, such that no shadows would cover symbols on the input unit and influence the user's operation.

Moreover, two ends of the liftable light shield are each provided with a short shaft, and two shaft holes corresponding to the two short shafts are formed respectively on two ends of a trough in the input unit. The trough corresponds to the liftable light shield and can receive the liftable light shield therein. When in use, the liftable light shield is lifted and the illuminators therein can irradiate light onto the input unit. When not in use, the liftable light shield can be completely received in the trough to store or hide the illuminators inside the input unit without affecting the appearance.

### BRIEF DESCRIPTION OF THE DRAWINGS

The present invention can be more fully understood by reading the following detailed description of the preferred embodiments, with reference made to the accompanying drawings, wherein:

FIG. 1 is a perspective view of a portable electronic device with an illumination indicator for input according to the present invention;

FIG. 2A is an exploded perspective view of a manually operating illumination unit of the portable electronic device according to the present invention;

FIG. 2B is an exploded perspective view of an automatically operating illumination unit of the portable electronic device according to the present invention;

FIG. 3 is cross-sectional view of a semiautomatically operating illumination unit of the portable electronic device according to the present invention;

FIG. 4 (PRIOR ART) is a partial cross-sectional view of a keyboard disclosed in U.S. Pat. No. 6,467,924;

FIG. 5 (PRIOR ART) is a side view of a conventional electronic device disclosed in U.S. Pat. No. 6,561,668;

FIG. 6A (PRIOR ART) is a side view of another conventional electronic device according to U.S. Pat. No. 6,561,668; and

FIG. 6B (PRIOR ART) is a partial side view of the electronic device shown in FIG. 6A.

### DETAILED DESCRIPTION OF THE PREFERRED EMBODIMENTS

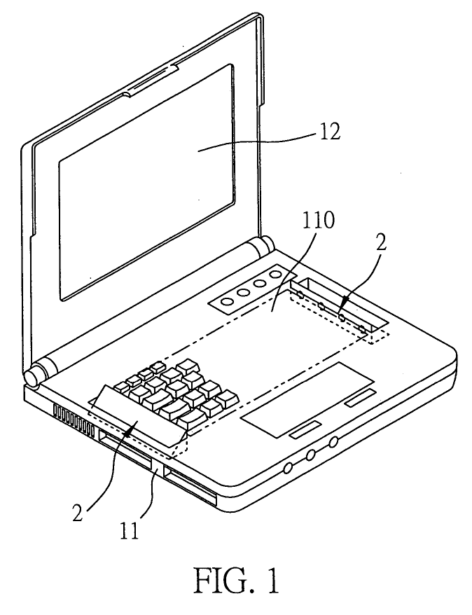

Referring to FIG. 1 showing a perspective view of a portable electronic device proposed in the present invention, this electronic device comprises a main body 11 having an input unit 110 provided thereon, and a display unit 12 pivotally connected to the main body 11. The main body 11 can be for example, a notebook computer, laptop computer, or portable computer; the input unit 110 can be for example a keyboard; and the display unit 12 can be for example a liquid crystal display. At least one illumination unit 2 is disposed on two sides of the input unit 110 respectively, and provides illumination for the input unit 110 in the dark or under a condition without sufficient light.

### First Embodiment of Illumination Unit

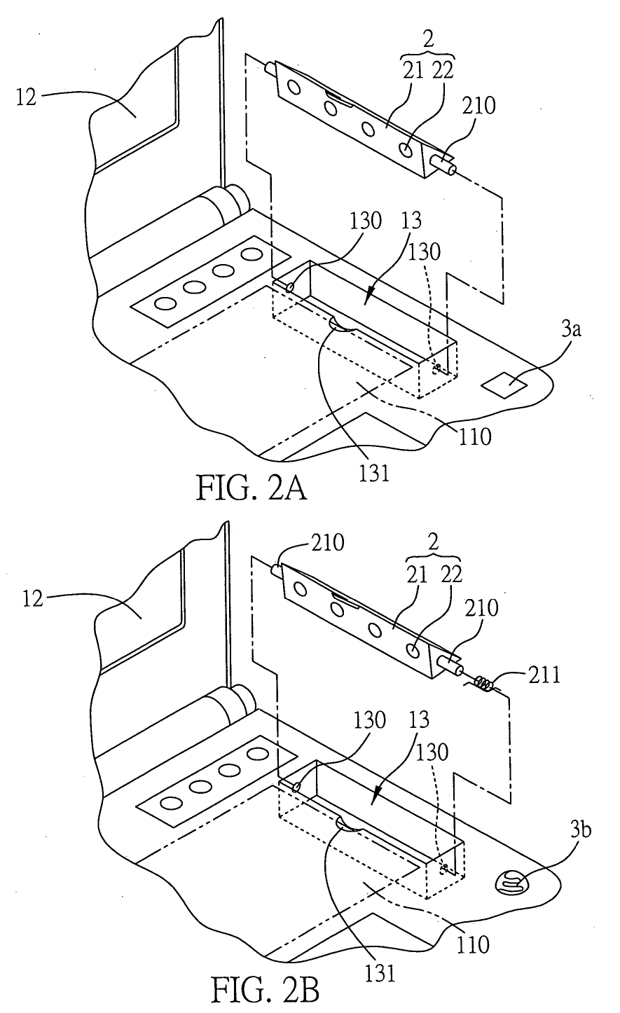

Referring to FIG. 2A, each of the illumination units 2 (only one is shown) comprises a liftable light shield 21 pivotally connected to the input unit 110, and a plurality of illuminators 22 provided in the liftable light shield 21, wherein the illuminators 22 can be for example LEDs (light emitting diodes), HB-LEDs (high-brightness light emitting diodes), or white light HB-LEDs. Moreover, the liftable light shield 21 is provided with two short shafts 210 at two ends thereof respectively. A trough 13 is formed in the input unit 110, for receiving the liftable light shield 21 therein. Two shaft holes 130 corresponding to the two short shafts 210 of the liftable light shield 21 are formed on two ends of the trough 13 respectively. Thus, the liftable light shield 21 is pivotally coupled via its short shafts 210 to the shaft holes 130 and stored in the corresponding trough 13.

Additionally, a recess 131 is provided on an edge of the trough 13, so as to allow the liftable light shield 21 received in the trough 13 to be manually lifted and opened via the recess 131. Thus, the liftable light shield 21 can be opened easily in the dark or under the condition without sufficient light, such that the illuminators 22 illuminate the input unit 110 for the user to operate the main body 11 under such condition.

### Second Embodiment of Illumination Unit

Referring to FIG. 2B, this second embodiment of the illumination units 2 (only one is shown) differs from the above first embodiment in that, in this embodiment, an elastic element 211 such as a torsion spring is provided on at least one of the two short shafts 210 of the liftable light shield 21 of the illumination unit 2. When the display unit 12 of the main body 11 is closed on the main body 11, the liftable light shield 21 is pressed down into the trough 13 by the display unit 12 and caused to deflect, making the elastic element 211 stored with elastic energy. When the display unit 12 is lifted and opened, the liftable light shield 21 can be automatically driven to open by the elastic energy of the elastic element 211. As a result, the liftable light shield 21 can be opened from or pressed into the trough 13 simultaneously along with the opening or closing action of the display unit 12. This embodiment illustrates automatic actions of the illumination unit 2 according to the present invention.

### First Embodiment of Control of Illuminators

Referring further to FIG. 2A, the illuminators 22 of each of the illumination units 2 can be actuated manually to irradiate light. More specifically, a switch 3a is provided on the input unit 110. After the liftable light shield 21 has been opened, the switch 3a can be switched on manually to make the illuminators 22 irradiate light.

### Second Embodiment of Control of Illuminators

Referring further to FIG. 2B, this second embodiment differs from the above first embodiment in that the manual switch 3a is replaced by an optical sensor 3b for detecting ambient light intensity. Under an environment without sufficient illumination or with completely no light, the optical sensor 3b would be in close circuit or an “on” status to actuate the illuminators 22 to irradiate light onto the input unit 110. On the contrary, under an environment with sufficient illumination, the optical sensor 3b would be in open circuit or an “off” status to switch off the illuminators 22. As a result, the illuminators 22 can be switched on or off automatically according to an ambient condition of illumination detected by the optical sensor 3b.

### Third Embodiment of Control of Illuminators

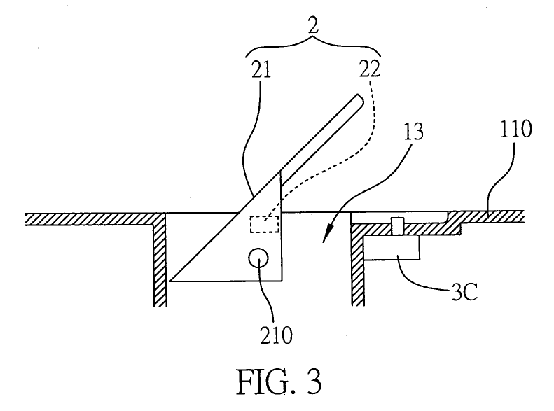

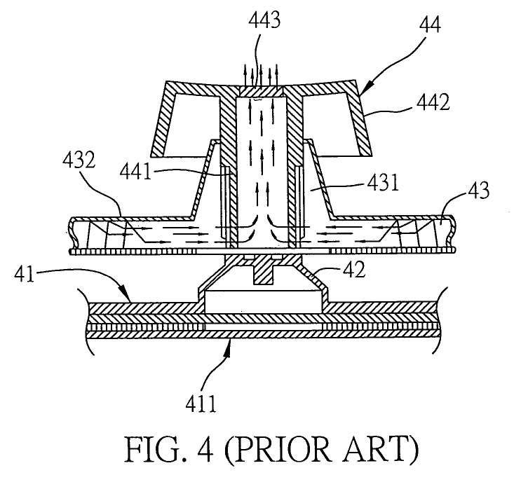

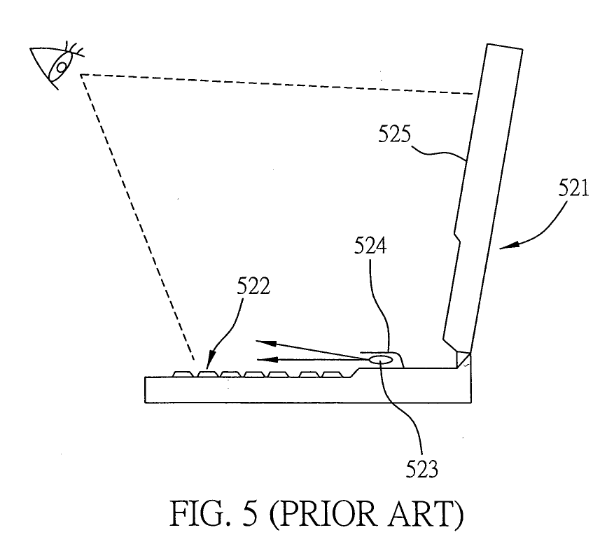

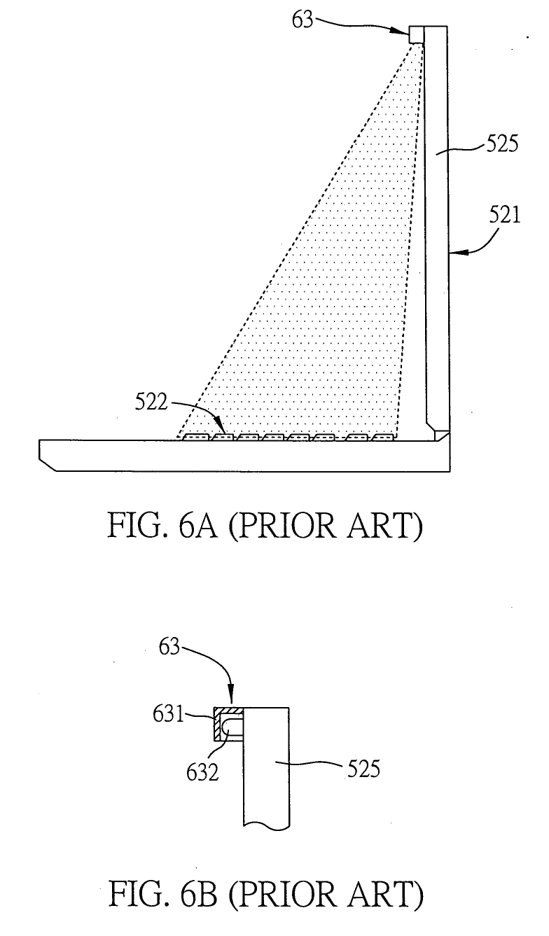

Referring to FIG. 3, this third embodiment differs from the above two embodiments in that the manual switch 3a or optical sensor 3b is replaced by an actuating switch 3c. The actuating switch 3c is provided on the input unit 110 at a position where the actuating switch 3c can be touched by the liftable light shield 21. When the liftable light shield 21 is closed and received in the trough 13, it touches and actuates the actuating switch 3c to become open circuit or in an “off” status, thus turning off the illuminators 22. On the contrary, if the liftable light shield 21 is lifted and opened, the actuating switch 3c is not in contact with the liftable light shield 21 and would be in close circuit or an “on” status, such that the illuminators 22 are switched on for illumination. As a result, the illuminators 22 are switched on automatically when the liftable light shield 21 is opened, and the illuminators 22 are switched off when the liftable light shield 21 is closed. This embodiment illustrates semiautomatic control of the illuminators 22 according to the present invention.

The foregoing opening methods of the liftable light shields 22 and control methods of the illuminators 22 are not limited to those combinations shown in the associated drawings, but can be modified with various combinations when necessary according to practical requirements to similarly achieve the above effects.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A portable electronic device with illumination indication for input, comprising:
a main body having an input unit;
a display unit pivotally connected to the main body; and
at least one illumination unit mounted on two sides of the input unit respectively and for illuminating the input unit, wherein the illumination unit comprises a liftable light shield pivotally connected to the input unit and a plurality of illuminators provided in the liftable light shield.

2. The portable electronic device of claim 1, wherein the liftable light shield comprises two short shafts formed on two ends thereof respectively, and the input unit is further provided with a trough corresponding to the liftable light shield, with two shaft holes being formed on two ends of the trough respectively corresponding to the two short shafts, so as to allow the liftable light shield to be pivotally coupled via the short shafts to the shaft holes and received in the trough.

3. The portable electronic device of claim 2, wherein a recess is formed on an edge of the trough, allowing the liftable light shield to be opened manually via the recess.

4. The portable electronic device of claim 2, wherein the liftable light shield further comprises an elastic element provided on at least one of the short shafts thereof, such that the liftable light shield is opened automatically via the elastic element when the display unit is opened, and the liftable light shield is pressed down into the trough when the display unit is closed.

5. The portable electronic device of claim 4, wherein the elastic element comprises a torsion spring.

6. The portable electronic device of claim 1, wherein the illuminators comprise light emitting diodes.

7. The portable electronic device of claim 1, wherein the illuminators comprise high brightness light emitting diodes.

8. The portable electronic device of claim 1, wherein the illuminators comprise white light high brightness light emitting diodes.

9. The portable electronic device of claim 1, wherein the illumination unit further comprises a switch provided on the input unit to control the illuminators.

10. The portable electronic device of claim 1, wherein the illumination unit further comprises an optical sensor provided on the input unit to control the illuminators.

11. The portable electronic device of claim 1, wherein the illumination unit further comprises an actuating switch provided on the input unit at a position where the actuating switch is touchable by the liftable light shield, so as to allow the actuating switch to be switched on or off by the liftable light shield to control the illuminators.

12. The portable electronic device of claim 1, wherein the main body is one selected from the group consisting of a notebook computer, laptop computer, and portable computer.

13. The portable electronic device of claim 1, wherein the input unit comprises a keyboard.

14. The portable electronic device of claim 1, wherein the display unit comprises a liquid crystal display.
